(19) United States
(12) Patent Application Publication
(10) Pub. No.: US 2008/0019409 A1
(43) Pub. Date: Jan. 24, 2008

(54) WAVELENGTH -TUNABLE SELECTIVE OPTOELECTRONIC FILTER

(75) Inventors: Michel Garrigues, La Tour De Salvagny (FR); Jean-Louis Leclercq, Morance (FR)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Centre National De La Recherche Scientifique

(21) Appl. No.: 11/773,684

(22) Filed: Jul. 5, 2007

Related U.S. Application Data
(63) Continuation of application No. PCT/FR06/00006, filed on Jan. 3, 2006.

(30) Foreign Application Priority Data
Jan. 7, 2005 (FR) 0500189

(51) Int. Cl. H01S 5/00

(52) U.S. Cl. 372/45.01

(57) ABSTRACT

A selective and wavelength-tunable optoelectronic filter comprising a resonant cavity placed between two partial reflectors (10, 12) such as Bragg mirrors, the resonant cavity being formed by a disk (16) of solid material having a high refractive index that constitutes a waveguide between the two partial reflectors (10, 12). The filter presents excellent selectivity.

The invention relates to a selective and wavelength-tunable optoelectronic filter, applicable in particular to wavelength demultiplexing of the various channels of an optical telecommunications system of the wavelength division multiplexed (WDM) type or of the dense wavelength division multiplexed (DWDM) type.

Selective and wavelength-tunable filters are known that are made up of micro-opto-electro-mechanical systems (MOEMS) components that can be fabricated using conventional microtechnology methods, and that can be tuned by mechanically deforming the materials of those components. Such filters are of the Fabry-Perot type and comprise a resonant cavity formed by a layer or “plate” of air placed between two parallel partial reflectors such as Bragg mirrors. The resonant wavelength is tunable by mounting at least one of the reflectors in elastically-deformable manner, and by moving it by means of electrostatic pressure produced by applying a control voltage between the two partial reflectors. That movement leads to a variation in the thickness of the resonant cavity and thus to a variation in the center wavelength of the filter.

When the reflectors defining the resonant cavity are plane and of small lateral dimensions, it is not possible to obtain spectral selectivity any better than 0.5 nanometers (nm), even though, when demultiplexing DWDM type signals, it is necessary to seek to obtain a value that is less than or equal to 0.2 nm.

This limitation is due to the fact that in a plane cavity, the natural divergence of a light beam limits the number of go-and-return trips that the beam can follow between the reflectors without escaping laterally from the cavity. This is a phenomenon known as “cavity instability”.

One known means for improving such selectivity is to impose an appropriate initial positive curvature on one of the two partial reflectors for refocusing the electromagnetic wave on each go-and-return trip, thereby increasing the number of go-and-return trips that the electromagnetic wave can follow in the resonant cavity without significant attenuation. That technique is described in document U.S. Pat. No. 6,645,784 (Tayebati et al.), but it is very complex and expensive to implement.

A particular object of the present invention is to provide a solution that is simple, effective, and inexpensive, to that problem of improving the spectral selectivity of filters of the above-specified type.

To this end, the invention provides a wavelength tunable selective optoelectronic filter comprising a resonant cavity formed between two partial reflectors, each constituted by a stack of layers that are transparent at the wavelength used, together with means for applying an electric field to the terminals of the reflectors for the purpose of wavelength tuning the filter, the filter being characterized in that the resonant cavity is constituted by a disk of solid material that is transparent at said wavelength and that has a high refractive index, forming a waveguide between the reflectors, and in that a first one of the reflectors is movable or deformable at least in part and is separated from the disk forming the resonant cavity by a plate of air.

The waveguide formed by the disk of transparent solid material of high refractive index that constitutes the resonant cavity confines the electromagnetic wave laterally while it is following go-and-return trips between the partial reflectors, and thus avoids lateral losses through the edges of the resonant cavity. This reduction in losses leads to a significant improvement in the spectral selectivity of the filter.

Furthermore, varying the thickness of the plate of air adjacent to the disk as a result of the movement of the above-mentioned movable or deformable portion enables the filter to be tuned in wavelength because the effective thickness of the resonant cavity formed by the above-mentioned disk is greater than the thickness of the disk due to the partial penetration of the reflected wave into the reflector.

Advantageously, the disk of high refractive index material constituting the resonant cavity has a diameter that is small, typically of the order of 10 micrometers (μm), so as to ensure as well as possible that the propagation of the resonant wave is quasi-monomode.

The first and second partial reflectors are typically constituted by respective stacks of materials that are transparent at the wavelengths used, one of said layers or a group of said layers in one of the reflectors or in each of the reflectors being movable or deformable and being separated from the disk of the resonant cavity by a plate of air.

In a particularly advantageous embodiment of the invention, the first reflector is made up of alternating layers of semiconductor material and layers of air and includes a movable or deformable semiconductor plate with p-type doping (or n type) that is opposite from the doping type of the other layers of semiconductor material of said first reflector.

The disk forming the resonant cavity is also made of semiconductor material having doping of the type opposite to that of the movable plate of the reflector.

Advantageously, the second partial reflector also comprises a stack of layers of semiconductor materials that are transparent at the wavelengths used, with one of the layers of semiconductor material or a group of said layers forming a movable or deformable plate that is separated from the disk forming the cavity by a layer of air, the doping of said movable or deformable plate being of the type opposite to that of the other layers of semiconductor material of the second partial reflector.

Under such circumstances, the doping of both above-mentioned movable or deformable plates is of the same type.

In a particular embodiment of the invention, the or each above-mentioned movable or deformable plate is a suspended plate connected by elastically-deformable arms of appropriate size to a stationary peripheral support.

Preferably, all of the layers of semiconductor material of the above-mentioned partial reflectors, and the disk forming the resonant cavity, are of the suspended type and they are connected by rigid or elastically-deformable arms as appropriate to a stationary peripheral support.

In a first embodiment, the means for wavelength-tuning the filter comprise two electrodes connected to stationary layers of semiconductor material of the partial reflectors situated on either side of the disk forming the resonant cavity and the movable plates, together with means for applying a control voltage between said electrodes.

The doping of the layers of semiconductor material of the reflectors, of the movable plates, and of the resonant cavity produces a structure of two diodes connected in opposite directions, thus making it possible to deform the movable plate either towards the stationary portion of the reflector of which it forms a part, or towards the resonant cavity, depending on the polarity of the applied voltage. This enables bi-directional actuation to be applied, thus enabling the resonant wavelength to be lengthened or shortened relative to its initial value.

When the other partial reflector of the filter of the invention also includes a movable or deformable plate, the wavelength-tuning means comprise three electrodes connected to the above-mentioned disk and to two stationary layers of semiconductor material of the reflectors situated on either side of the disk and the respective movable plate, together with means for applying identical voltages between the electrodes connected to the disk and the electrodes connected to the above-mentioned stationary layers.

Under such circumstances, it is possible to deform both of the movable plates situated on either side of the resonant cavity simultaneously, thereby doubling the wavelength-tuning range, thus making it possible for example to cover both the C and the L bands (1525 nm-1562 nm, and 1570 nm-1615 nm) in a WDM type telecommunications system.

The invention can be better understood and other details, characteristics, and advantages thereof appear more clearly on reading the following description made by way of example and with reference to the accompanying drawings, in which:

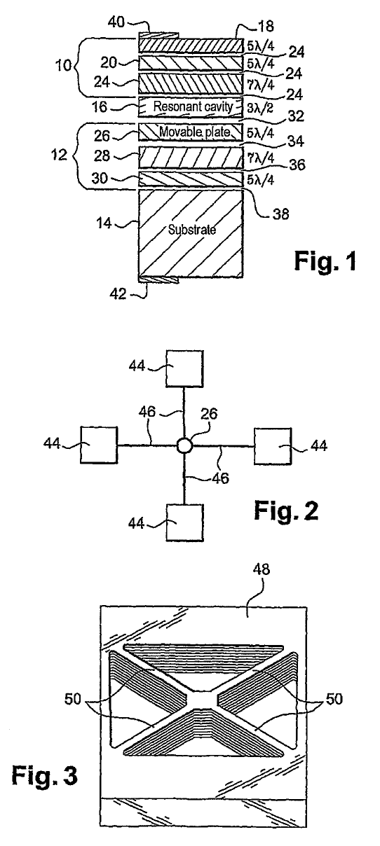

FIG. 1 is a diagram showing the structure of a filter of the invention;

FIG. 2 is a diagrammatic plan view of an element of the filter;

FIG. 3 is a diagrammatic perspective view of a variant embodiment;

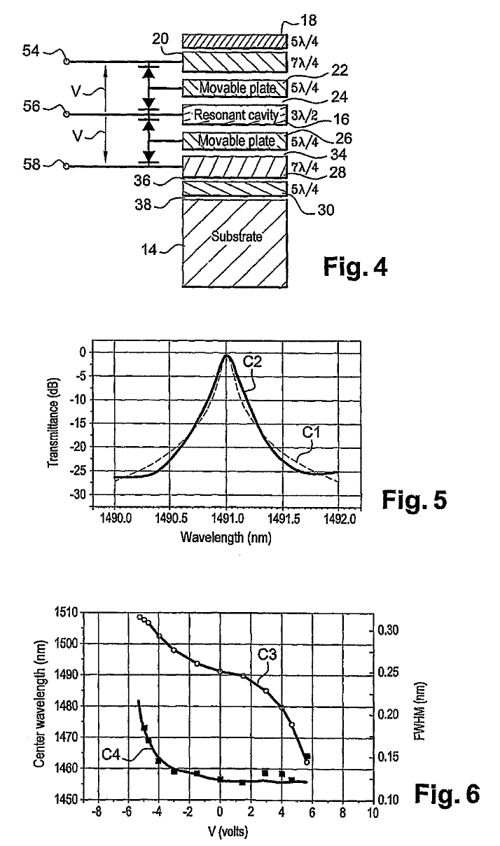

FIG. 4 is a diagram showing the general structure of a variant embodiment of the filter of the invention;

FIG. 5 is a graph showing theoretical and measured transmittances for a filter of the invention; and

FIG. 6 is a graph showing variations in the center wavelength of the −3 dB passband of the filter of the invention as a function of the control voltage.

Reference is made initially to FIG. 1 which is a diagram showing the general structure of a filter of the invention, essentially comprising two Bragg mirrors 10 and 12 carried by a substrate 14 and having situated between them a disk 16 of solid material having a high refractive index and constituting a resonant cavity at the wavelength under consideration (the disk has a thickness equal to k.λ/2, where k is equal to 3 in the example shown).

The top Bragg mirror 10 in FIG. 1 comprises alternating layers of semiconductor material 18, 20, 22 forming quarterwave plates that are separated from one another, and from the resonant disk 16, by quarterwave plates 24 of air, and the bottom Bragg mirror 12 is made up of layers 26, 28, and 30 of semiconductor material which are quarterwave plates and separated from one another and from the resonant disk 16 by respective quarterwave plates 32, 34, 36, and 38, of air.

The various layers of semiconductor material in the Bragg mirrors are stationary, i.e. they are not displaceable or not deformable, with the exception of one layer adjacent to the disk 16, for example the layer 26 of the bottom Bragg mirror 12 which is movable or deformable axially towards and away from the disk 16.

The thicknesses of the various layers of semiconductor material forming the Bragg mirrors are given in FIG. 1, and they are equal to (2 k+1)λ/4, where k is equal in this example to 2 or 3 for reasons of mechanical optimization. In this example, the plates of air have thicknesses equal to (2 k+1)λ/4, where k=0, with the exception of the plates 32 and 34 situated on either side of the movable plate 26 of the Bragg mirror 12, with these plates having thickness equal to 3λ/4.

The movable plate 26 is moved in one direction or the other under the control of a voltage applied between a top contact 40, e.g. secured to the top Bragg mirror 10, and a bottom contact 42, e.g. secured to the substrate 14 or to a semiconductor plate of the bottom Bragg mirror 12, with the direction in which the movable plate 26 moves depending on the polarity of the applied voltage. The various semiconductor plates of the Bragg mirrors 10 and 12 all have the same type of doping (e.g. n), with the exception of the movable plate 26 which has doping of the opposite type (e.g. p).

The movement of the movable plate 26 in one direction or the other modifies the thickness of the air plate 32 that lies between said movable plate 26 and the resonant disk, thereby varying the center wavelength of transmission for the filter of the invention because the effective thickness of the resonant cavity of said filter is greater than the thickness of the disk 16 due to the partial penetration of the reflected wave into the bottom Bragg mirror 12.

Because of its solid structure and its high refractive index, the resonant disk 16 constitutes a waveguide between the two Bragg mirrors 10 and 12, thereby greatly limiting losses from the resonant electromagnetic wave by lateral leakage.

In order to ensure quasi-monomode propagation of the wave in the resonant disk 16, the diameter of the disk is selected to be relatively small, e.g. about 10 μm.

The reduction of lateral losses from the resonant cavity increases the reflectivity of the Bragg mirrors and thus the number of go-and-return trips of the resonant wave, thereby obtaining better selectivity for the filter of the invention.

The movable plate 26 is advantageously a structure that is suspended, e.g. in the manner shown in FIG. 2.

In this example, the movable plate 26 is in the form of a disk of circular outline, having a diameter of about 10 μm, and connected to anchor studs 44 by four arms 46 that extend outwards from the disk 26 at 90° from one another, these arms 46 being elastically deformable in bending.

In the embodiment shown diagrammatically in FIG. 3, all of the plates of the Bragg mirrors 10 and 12, and also the resonant disk 16, comprise respective central disks having a diameter of about 10 μm that are suspended from a fixed frame 48 in the form of a rectilinear parallelepiped by means of arms 50 that extend diagonally inside the frame 48, these arms being of a width of about 5 μm and a length of 50 μm to 70 μm.

The structure shown in FIG. 3 is obtained by a combination of deep ionic etching and selective chemical etching.

In the embodiment of the filter shown diagrammatically in FIG. 4, the two semiconductor plates 22 and 26 of the Bragg mirrors 10 and 12 that are situated on either side of the resonant disk 16 are movable plates and they are separated from the resonant disk 16 by air plates 24 and 34 respectively each of thickness equal to 3λ/4.

The stationary semiconductor plates 18, 20, 28, 30 of the two Bragg mirrors, and the disk 16 have n-type doping, while the movable plates 22 and 26 have p-type doping. This produces a structure of diodes 52 mounted in opposite directions between the semiconductor plates 20, 22 of the first Bragg mirror 10, the resonant disk 16, and the semiconductor plates 26, 28 of the second Bragg mirror 12. Control electrodes 54, 56, and 58 are connected by way of example to the semiconductor layer 20 of the first Bragg mirror 10, to the resonant disk 16, and to the semiconductor layer 28 of the second Bragg mirror 12, in order to apply two voltages V between the electrodes 54 and 56 and between the electrodes 56 and 58, these two voltages being identical relative to the common electrode 56.

Depending on the polarity of the voltage V, the movable plates 22 and 26 move simultaneously away from the resonant disk 16, thereby lengthening the resonant wavelength, or simultaneously towards the resonant disk 16, thereby shortening the resonant wavelength.

This makes it possible to double the wavelength tuning range of the filter of the invention.

The filter can be made using layers of material having a low refractive index, e.g. of SiO₂, and of a material having a high refractive index, e.g. TiO₂. A filter having the structure of FIG. 1 can then correspond to the following optical formula:
L(HL) ˆ9 6H AAA (HL) ˆ7H
where L designates an λ/4 layer of SiO₂, H designates a λ/4 layer of TiO₂, A designates a λ/4 layer of air, L(HL) ˆ9 designates the top Bragg mirror 10 having nine different plates, 6H designates the resonant disk having a high refractive index and thickness equal to 3λ, and AAA (HL) ˆ7H designates the bottom Bragg mirror 12 with its air plate AAA of adjustable thickness.

Such a structure presents selectivity of 0.1 nm for a center wavelength of 1550 nm. Its tuning range is greater than 50 nm, without loss of selectivity.

A filter of the invention having the structure shown diagrammatically in FIG. 4 then satisfies the following optical formula:
(HL) ˆ6H AAA 6H AAA (HL) ˆ7H

This filter presents selectivity of about 0.1 nm for a center wavelength of 1550 nm, and its tuning range exceeds 100 nm about the center wavelength.

In a variant, a filter of the invention may be made up of plates of indium phosphide (InP) having the thicknesses given in FIG. 4, arranged in alternation with plates of air having thickness equal to λ/4 with the exception of the plates on either side of the resonant disk 16 which have thickness equal to 3λ/4, the disk 16 likewise being of indium phosphide. In this embodiment, the various plates of indium phosphide are separated from one another by spacers of InGaAs.

The tuning range is greater than 100 nm and enables both the C and the L bands of a WDM type optical telecommunications system to be covered.

FIG. 5 is a graph showing the transmittance of the filter of the invention as a function of wavelength, the filter having the structure shown diagrammatically in FIG. 1. Dashed line curve C1 is a theoretical curve, while continuous line curve C2 is an experimental curve obtained using the filter of FIG. 1 with its semiconductor layers and the disk 16 being made of indium phosphide (InP). It can be seen that the two curves C1 and C2 are very close to each other and that the passband measured at −3 dB is less than 0.15 nm. Rejection of −20 dB is obtained at ±0.45 nm of the center wavelength, and the maximum rejection is better than 25 dB.

In the graph of FIG. 6, curve C3 shows variation in the center wavelength of the FIG. 1 filter as a function of the voltage V between the electrodes 40 and 42, and curve C4 represents variation in the −3 dB or full width at half-maximum (FWHM) passband as a function of the control voltage V.

The curve C3 shows that wavelength tuning is obtained over a range of 45 nm without significant degradation in selectivity for a control voltage V lying in the range −6 volts to +6 volts. These curves C3 and C4 were plotted from experimental measurements taken on a filter having the structure of FIG. 1 and in which the Bragg mirrors and the resonant disk were formed by layers of indium phosphide, as mentioned above.

1. A wavelength tunable selective optoelectronic filter comprising a resonant cavity formed between two partial reflectors, each constituted by a stack of layers that are transparent at the wavelength used, together with means for applying an electric field to the terminals of the reflectors for the purpose of wavelength tuning the filter, wherein the resonant cavity is constituted by a disk of solid material that is transparent at said wavelength and that has a high refractive index, forming a waveguide between the reflectors, and wherein a first one of the reflectors is movable or deformable at least in part and is separated from the disk forming the resonant cavity by a plate of air.

2. A filter according to claim 1, wherein the second of the reflectors is movable or deformable at least in part and separated from the disk forming the resonant cavity by a plate of air.

3. A filter according to claim 1, wherein the disk of high-index material has a small diameter, for quasi-monomode propagation of the resonant wave.

4. A filter according to claim 1, wherein the first reflector comprises alternating layers of air and layers or plates of solid material that is transparent to said wavelength, and includes a movable or deformable layer of solid material that is separated from the disk by the above-specified plate of air.

5. A filter according to claim 1, wherein the second reflector comprises alternating layers of air and layers or plates of solid material transparent at said wavelengths, one of said layers of solid material forming a movable or deformable plate that is separated from the disk of the resonant cavity by a layer of air.

6. A filter according to claim 4, wherein the layers of solid material in the two reflectors are layers of semiconductor material, and wherein the moving layer of the or each above-mentioned reflector has doping opposite to that of the doping of the other layers of solid material of the reflector.

7. A filter according to claim 6, wherein the doping of both moving layers is of the same type.

8. A filter according to claim 4, wherein the or each moving layer is a suspended layer.

9. A filter according to claim 4, wherein the layer of air separating the disk forming the resonant cavity from a moving layer has a thickness equal to (2 k+1)2/4.

10. A filter according to claim 1, wherein the disk forming the resonant cavity has a thickness equal to k.A/2.

11. A filter according to claim 1 wherein the disk forming the resonant cavity is of circular outline.

12. A filter according to claim 1, all of the layers of solid material of the two partial reflectors, and the disk forming the resonant cavity, are suspended, and wherein the filter is made by ionic etching and by selective chemical etching.

13. A filter according to claim 4, wherein the wavelength tuning means comprise electrodes connected to layers of semiconductor material situated on opposite sides of the disk and said moving layer, together with means for applying a control voltage to said electrodes.

14. A filter according to claim 5, wherein the wavelength tuning means comprise a first electrode connected to a stationary layer of semiconductor material of one of the reflectors, an electrode connected to the disk forming the resonant cavity, and a third electrode connected to a stationary layer of semiconductor material of the other reflector, together with means for applying identical voltages between the second and third electrodes, and between the second and third electrodes.
